(19) United States
(12) Patent Application Publication
(10) Pub. No.: US 2025/0107216 A1
(43) Pub. Date: Mar. 27, 2025

(54) HIGH DENSITY CAPACITOR AND MANUFACTURING METHOD THEREFOR

(71) Applicant: Electronics and Telecommunications Research Institute, Daejeon (KR)

(72) Inventors: SangHwa YOO, Daejeon (KR); Heuk PARK, Daejeon (KR); Joon Ki LEE, Sejong-si (KR)

(21) Appl. No.: 18/893,820

(22) Filed: Sep. 23, 2024

(30) Foreign Application Priority Data
Sep. 25, 2023 (KR) 10-2023-0128335

(51) Int. Cl. H01L 27/06; H01L 29/66; H01L 29/94

(52) U.S. Cl. CPC H10D 84/811; H10D 1/047; H10D 1/66; H10D 1/692

(57) ABSTRACT

A high-density capacitor and a method for manufacturing the same are disclosed. The high-density capacitor includes a metal-oxide-semiconductor (MOS) capacitor having a silicon layer with a dopant concentration of at least 1×1020 cm-3; a first dielectric layer formed on above the silicon layer, and a first metal layer formed above the first dielectric layer.

### CROSS-REFERENCE TO RELATED APPLICATIONS

The present application claims the benefit of Korean Patent Application No. 10-2023-0128335, filed on Sep. 25, 2023, which application is hereby incorporated herein by reference.

### TECHNICAL FIELD

The present disclosure relates to a high-density capacitor and a method for manufacturing the same. More specifically, the present disclosure relates to a high-density on-chip capacitor using a silicon photonics chip manufacturing process and a manufacturing method therefor.

### BACKGROUND

The content to be described below simply provides background information related to the present embodiment and does not constitute the related art.

A silicon photonics technology is a technology for integrating various photonics elements into one chip using a commercial complementary metal-oxide-semiconductor (CMOS) semiconductor process. With the silicon photonics technology, elements for optical communication are mass produced so that an optical communication module is made at low cost and with a small size and high capacity. In particular, a silicon photonics optical transmission element and a silicon photonics optical reception element are being considered as key elements for coping with recently exponentially increasing data center traffic and communication traffic. For electrical Direct Current (DC) coupling or electrical Alternating Current (AC) coupling of this silicon photonics element to the outside of the chip, a high-density on-chip capacitor with high capacitance per unit area is required.

One of metal-insulator-metal capacitor (MIM capacitor) structures for increasing integration of an on-chip capacitor of the related art is a structure in which a high-k material with a high dielectric constant is used as a dielectric material or a distance between metal layers is minimized, which is disclosed in US2009/0200638 A1. This structure has a distance between the metal layers of several tens of nanometers. However, a capacitor with the distance between metal layers of tens of nanometers requires high-end semiconductor processes, making the capacitor difficult to apply to a silicon photonics element.

Alternatively, there is a method of manufacturing an MIM capacitor with a distance between metal layers of 1 micrometer. Such an MIM capacitor can be manufactured using a production process for a silicon photonics element, but a large area is required to achieve a picoFrad-level capacitance.

Another on-chip capacitor is a capacitor using a MOS structure of a metal-oxide-semiconductor field effect transistor (MOSFET) element disclosed in US2010/0226166 A1. However, a MOS capacitor is difficult to implement in the production process for a silicon photonics element.

Accordingly, an on-chip capacitor with a high capacitance per unit area in which the production process for a silicon photonics element is used is required.

### SUMMARY

According to at least one embodiment, the present disclosure provides a high-density capacitor including a metal-oxide-semiconductor (MOS) capacitor. The MOS capacitor includes a silicon layer with a dopant concentration of at least 1× 1020 cm-3; a first dielectric layer formed on above the silicon layer; and a first metal layer formed above the first dielectric layer.

According to another embodiment, the present disclosure provides a method of manufacturing a high-density capacitor including a MOS capacitor. The method includes doping a silicon layer to have a dopant concentration of at least 1×1020 cm-3; forming a first dielectric layer over the silicon layer; and forming a first metal layer over the first dielectric layer.

### BRIEF DESCRIPTION OF THE DRAWINGS

FIG. 1 is a cross-sectional view showing a MOS capacitor according to an embodiment of the present disclosure.

FIG. 2 is a cross-sectional view showing a high-density capacitor according to an embodiment of the present disclosure.

FIG. 3 is a cross-sectional view showing a silicon photonics chip according to an embodiment of the present disclosure.

FIG. 4A is a graph showing an S11 parameter of a silicon optical modulator according to an embodiment of the present disclosure.

FIG. 4B is a graph showing an S21 parameter of the silicon optical modulator according to the embodiment of the present disclosure.

### DETAILED DESCRIPTION

The present disclosure may provide an on-chip capacitor with a high capacitance per unit area.

The features of the present disclosure are not limited to the features mentioned above, and other features not mentioned can be clearly understood by those skilled in the art from the description below.

Hereinafter, some exemplary embodiments of the present disclosure will be described in detail with reference to the accompanying drawings. In the following description, like reference numerals preferably designate like elements, although the elements are shown in different drawings. Further, in the following description of some embodiments, a detailed description of known functions and configurations incorporated therein will be omitted for the purpose of clarity and for brevity.

Additionally, various terms such as first, second, A, B, (a), (b), etc., are used solely to differentiate one component from the other but not to imply or suggest the substances, order, or sequence of the components. Throughout this specification, when a part ‘includes’ or ‘comprises’ a component, the part is meant to further include other components, not to exclude thereof unless specifically stated to the contrary. The terms such as ‘unit’, ‘module’, and the like refer to one or more units for processing at least one function or operation, which may be implemented by hardware, software, or a combination thereof.

The following detailed description, together with the accompanying drawings, is intended to describe exemplary embodiments of the present invention, and is not intended to represent the only embodiments in which the present invention may be practiced.

In the present disclosure, when a part such as a layer, film, region, or plate is said to be on or above another part, this includes not only a case where the part is directly on the other part, but also a case where the other part is located in the middle. On the other hand, when a part is said to be directly on another part, this means that no other part is located in the middle. Further, when a part is said to be on or under another part, this refers to the part being located on or under the other part in a direction indicated in a figure, and does not necessarily mean the part being on or under the other part in a direction perpendicular to a ground surface.

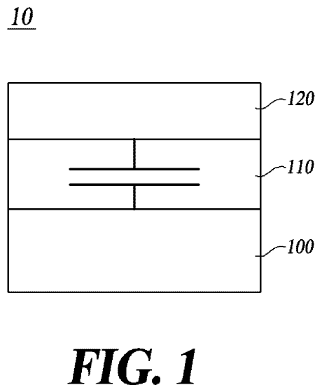

FIG. 1 is a cross-sectional view showing a MOS capacitor according to an embodiment of the present disclosure.

Referring to FIG. 1, a metal-oxide-semiconductor (MOS) capacitor 10 may include a silicon layer 100, a first dielectric layer 110, and a first metal layer 120.

The silicon layer 100 may include doped silicon. The silicon layer 100 preferably has low resistance to operate as a capacitor. The silicon layer 100 may include a high concentration of dopant to have the low resistance. That is, the silicon layer 100 may include silicon doped with a doping concentration. According to an embodiment of the present disclosure, a doping concentration of the silicon layer 100 may be 1×10²⁰ cm⁻³. According to another embodiment, the doping concentration of the silicon layer 100 may be higher than 1×10²⁰ cm⁻³.

The first dielectric layer 110 may be formed over the silicon layer 100. The first dielectric layer 110 may include a dielectric material. The first dielectric layer 110 may include oxide. For example, the first dielectric layer 110 may include silicon oxide (SiO₂).

The first dielectric layer 110 may have a predefined thickness. The thickness of the first dielectric layer 110 may be, for example, 500 nm to 800 nm.

The first metal layer 120 may be formed over the silicon layer 100 and the first dielectric layer 110. That is, the first dielectric layer 110 may be formed between the first metal layer 120 and the silicon layer 100. The first metal layer 120 may include a metal having conductivity. The metal included in the first metal layer 120 may have low resistance.

The silicon layer 100 and the first metal layer 120 may have the same area. Alternatively, the area of the silicon layer 100 and the area of the first metal layer 120 may be different from each other. The silicon layer 100 and the first metal layer 120 may be formed to be parallel with each other. The silicon layer 100 and the first metal layer 120 may each be electrically connected to different power supplies (e.g. VCC 1 and VCC 2). Alternatively, the first metal layer 120 may be connected to a power supply and the silicon layer 100 may be grounded. The silicon layer 100 and/or the first metal layer 120 may be connected to power or ground through vias and/or other metal layers, but is not limited thereto.

A current does not flow between the silicon layer 100 and the first metal layer 120 due to the first dielectric layer 110 present between the silicon layer 100 and the first metal layer 120. That is, electric charges are accumulated in the silicon layer 100 and the first metal layer 120, which can function as a capacitor.

A capacitance C_{MOS} of the MOS capacitor 10 is given as shown in Equation 1.

$${C}_{MOS} = \frac{{ε}_{r} {ε}_{0} {A}_{MOS}}{{d}_{MOS}} \qquad [ Equation 1 ]$$

Here, εᵣ indicates relative permittivity, ε₀ is vacuum permittivity, A_{MOS} is an area of the MOS capacitor 10, and d_{MOS} is a distance between the silicon layer 100 and the first metal layer 120, that is, a thickness of the first dielectric layer 110.

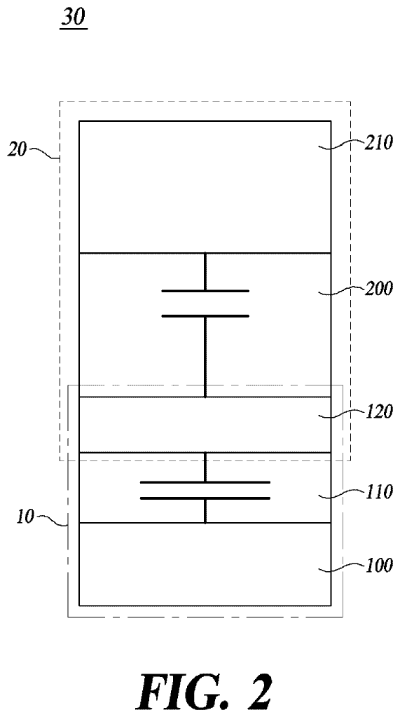

FIG. 2 is a cross-sectional view showing a high-density capacitor according to an embodiment of the present disclosure.

Referring to FIG. 2, a high-density capacitor 30 may include a MOS capacitor 10 and a metal-insulator-metal (MIM) capacitor 20.

The MOS capacitor 10 may include a silicon layer 100, a first dielectric layer 110, and a first metal layer 120. The MOS capacitor 10 may be the same MOS capacitor as that shown in FIG. 1.

The MIM capacitor 20 may include a first metal layer 120, a second dielectric layer 200, and a second metal layer 210.

The first metal layer 120 may be formed over the first dielectric layer 110. That is, the first dielectric layer 110 may be formed between the first metal layer 120 and the silicon layer 100. The first metal layer 120 may include a metal having conductivity. The metal included in the first metal layer 120 may be a metal with low resistance.

According to an embodiment of the present disclosure, the first metal layer of the MIM capacitor 20 may be the same metal layer as the first metal layer of the MOS capacitor 10. That is, the MOS capacitor 10 and the MIM capacitor 20 may be stacked and share at least a portion of the first metal layer 120

The second dielectric layer 200 may be formed over the first metal layer 120. The second dielectric layer 200 may include a dielectric material. The second dielectric layer 200 may include oxide. For example, the second dielectric layer 200 may include silicon oxide (SiO₂). As another example, the second dielectric layer 200 may include the same material as the first dielectric layer 110. In other words, the first dielectric layer 110 and the second dielectric layer 200 may be the same component.

The second dielectric layer 200 may have a predefined thickness. A thickness of the second dielectric layer 200 may be, for example, 1 μm to 1.5 μm.

The second metal layer 210 may be formed over the second dielectric layer 200. That is, the second dielectric layer 200 may be formed between the first metal layer 120 and the second metal layer 210. The second metal layer 210 may include a metal having conductivity. The metal included in the second metal layer 210 may be a metal with low resistance. The metal included in the second metal layer 210 may be the same material as the metal included in the first metal layer 120. In other words, the first metal layer 120 and the second metal layer 210 may differ only in shape and position.

The first metal layer 120 and the second metal layer 210 may have the same area. On the other hand, the areas of the first metal layer 120 and the second metal layer 210 may be different from each other. The first metal layer 120 and the second metal layer 210 may be connected to different power supplies. Alternatively, the first metal layer 120 may be connected to a power supply and the second metal layer 210 may be grounded.

A capacitance C_{MIN} of the MIM capacitor 20 is given as shown in Equation 2.

$${C}_{MIM} = \frac{{ε}_{r} {ε}_{0} {A}_{MIM}}{{d}_{MIM}} \qquad [ Equation 2 ]$$

Here, εᵣ indicates relative permittivity, so indicates vacuum permittivity, A_{MIN} indicates an area of the MIM capacitor 20, and d_{MIN} indicates a distance between the first metal layer 120 and the second metal layer 210, that is, a thickness of the second dielectric layer 200.

According to an embodiment of the present disclosure, the first dielectric layer 110 and the second dielectric layer 200 may be made of the same material. That is, relative permittivity of the MIM capacitor 20 and the MOS capacitor 10 may be the same.

The MIM capacitor 20 and the MOS capacitor 10 may have the same area. For example, in a silicon photonics chip, the MOS capacitor 10 and the MIM capacitor 20 may be formed as much as an area allocated for a capacitor. When the MOS capacitor 10 and the MIM capacitor 20 are connected in parallel, that is, when the silicon layer 100 and the second metal layer 210 are electrically connected, a capacitance Cₜₒₜₐₗ of the high-density capacitor 30 including the MIM capacitor 20 and the MOS capacitor 10 is expressed as shown in Equation 3.

$${C}_{total} = {C}_{MOS} + {C}_{MIM} = {ε}_{r} {ε}_{0} A ( \frac{1}{{d}_{MOS}} + \frac{1}{{d}_{MIM}} ) \qquad [ Equation 3 ]$$

According to an embodiment of the present disclosure, d_{MIN} may be about twice dos. For example, d_{MOS} may be 500 nm and d_{MIN} may be 1.0 μm. In this case, a capacitance of the high-density capacitor 30 may be about three times that of the MIM capacitor 20.

That is, with the high-density capacitor 30 according to an embodiment of the present disclosure, it is possible to increase a capacitance per area by about 3 times compared to the MIM capacitor 20.

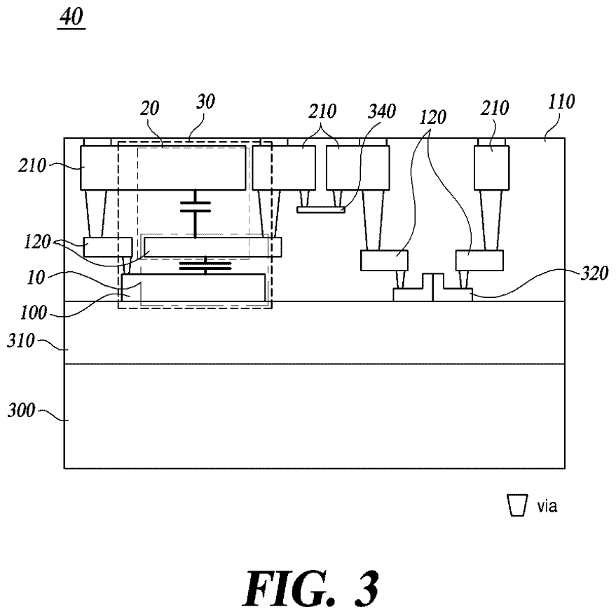

FIG. 3 is a cross-sectional view showing a silicon photonics chip according to an embodiment of the present disclosure.

Referring to FIG. 3, a silicon photonics chip 40 may include a substrate 300, a buried oxide layer 310, the high-density capacitor 30, the first metal layer 120, the second metal layer 210, and a silicon optical modulator 320. The silicon photonics chip 40 shown in FIG. 3 uses the high-density capacitor 30 of FIG. 2 as a bypass capacitor. For example, one end of the high-density capacitor 30 may be connected to ground, while the other end of the high-density capacitor 30 may be connected to power. Here, the silicon photonics chip 40 may apply power to the silicon optical modulator 320 through a termination resistor 340, but it is not limited to this example

The substrate 300 may include a semiconductor material. The semiconductor material may be at least one of silicon (Si), sapphire, gallium Nitride (GaN), and gallium oxide (Ga2O3), but is not necessarily limited thereto and may be a variety of materials.

The substrate 300 may have a single crystal structure. Here, the single crystal structure refers to a structure in which an entire object is a single crystal, that is, a structure that is a single grain. In the single crystal structure, a crystallographic direction and structure are the same at any point on the object.

The substrate 300 may be made of a material with high purity. For example, the substrate 300 may be made of silicon with eleven-nine (11N) purity. 11N means purity of 99.999999999%.

The substrate 300 may include a dopant. The dopant may be at least one element selected from among boron (B), aluminum (Al), gallium (Ga), phosphorus (P), and arsenic (As).

The buried oxide layer 310 may be formed over the substrate 300. The buried oxide layer 310 may contain oxide. The buried oxide layer 310 may include silicon oxide. The substrate 300, the high-density capacitor 30, the substrate 300, and the silicon optical modulator 320 may be electrically insulated by the buried oxide layer 310.

The high-density capacitor 30 and the silicon optical modulator 320 may be formed over the buried oxide layer 310. The high-density capacitor 30 and the silicon optical modulator 320 may be formed to be spaced apart from each other. In other words, the high-density capacitor 30 and the silicon optical modulator 320 may not be in physical contact with each other. The first metal layer 120 may be formed over the silicon optical modulator 320.

The silicon optical modulator 320 may be connected to the first metal layer 120. The silicon optical modulator 320 may be connected to the first metal layer 120 using a conductor (e.g., via). That is, the silicon optical modulator 320 and the first metal layer 120 may be electrically connected.

The first metal layer 120 and the second metal layer 210 may be connected to each other. The first metal layer 120 and the second metal layer 210 may be connected to each other using a conductor (e.g., via). In other words, the first metal layer 120 and the second metal layer 210 may be electrically connected to each other.

The first metal layer 120 and the second metal layer 210 may be discontinuous layers. That is, the first metal layer 120 and the second metal layer 210 may each include a plurality of separated regions.

Among the components shown in FIG. 3, the high-density capacitor 30, the first metal layer 120, the second metal layer 210, and the silicon optical modulator 320 may be formed to be buried in the first dielectric layer 110. That is, the high-density capacitor 30, the first metal layer 120, the second metal layer 210, and the silicon optical modulator 320 may be formed inside the first dielectric layer 110. Here, the second dielectric layer 200 included in the high-density capacitor 30 may be a part of the first dielectric layer 110.

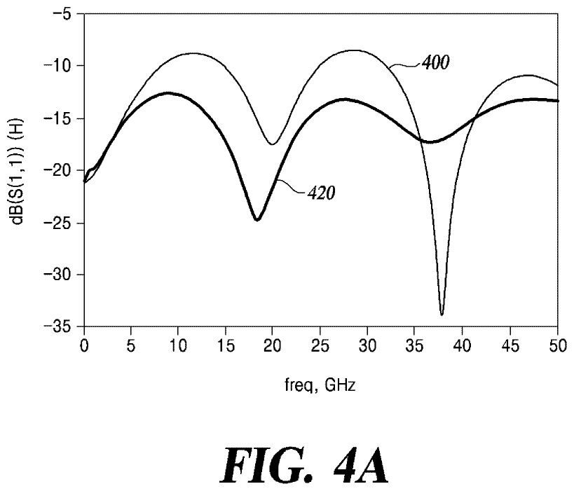

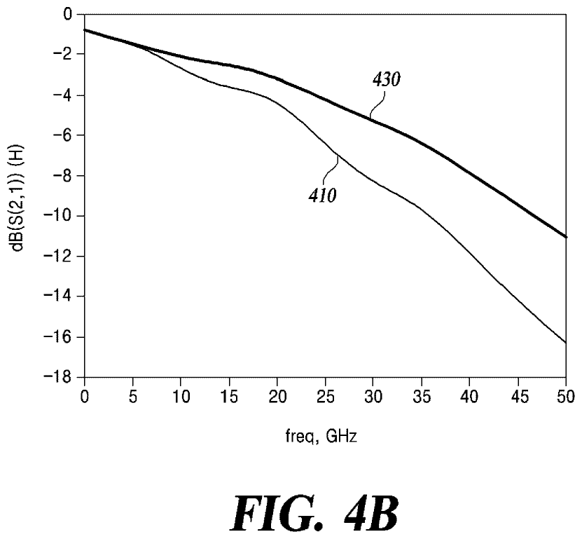

FIGS. 4A and 4B are graphs showing an S parameter of the silicon optical modulator.

FIG. 4A is a graph showing an S11 parameter of the silicon optical modulator according to an embodiment of the present disclosure.

FIG. 4B is a graph showing an S21 parameter of the silicon optical modulator according to an embodiment of the present disclosure.

FIGS. 4A and 4B are graphs showing the S11 parameter and the S21 parameter when power is supplied to the silicon optical modulator using wire bonding with a wire bonding inductance of 400 pH. In FIGS. 4A and 4B, curves 400 and 410 show the simulation results for a silicon photonics chip that does not include the high-density capacitor 30, while curves 420 and 430 show the simulation results for the silicon photonics chip 40 that includes the high-density capacitor 30.

Referring to curve 400 in FIG. 4A, a silicon optical modulator of the silicon photonics chip that does not include the high-density capacitor 30 may have the S11 parameter exceeding 10 dB. Further, referring to curve 410 in FIG. 4B, a bandwidth when the S21 parameter is 6 dB is about 25 GHz.

In contrast, the curve 420 in FIG. 4A indicates that the silicon optical modulator 320 of the silicon photonics chip 40 including the high-density capacitor 30 has a maximum value of the S11 parameter of 10 dB or less, and the curve 430 in FIG. 4B indicates that the bandwidth when the S21 parameter is 6 dB is approximately 35 GHz. That is, in the case of the silicon photonics chip 40 including the high-density capacitor 30, a reflection property and a transmission property of the silicon optical modulator 320 are improved.

The silicon photonics chip 40 according to the embodiment of the present disclosure may be manufactured using a silicon photonics process in which the distance between the metal layers is about 1 μm to 1.5 μm, and a distance between the silicon layer 100 and the metal layer 120 is about 500 nm to 800 nm. The high-density capacitor 30 according to an embodiment of the present disclosure may use the silicon phononics process to provide the MOS capacitor 10 with a capacitance per area twice that of the MIM capacitor 20.

According to an embodiment of the present disclosure, it is possible to provide an on-chip capacitor with a high capacitance per unit area by including a MOS capacitor having silicon doped at a high concentration. As an example, the MOS capacitor 10 shown in FIG. 1 is able to achieve the same capacitance with half the area compared to a conventional MIM capacitor. In another example, the high-density capacitor 30 shown in FIG. 2 is able to achieve the same capacitance with one-third of the area.

The features of the present disclosure are not limited to the effect mentioned above, and other features not mentioned may be clearly understood by those skilled in the art from the description above.

The components described in the example embodiments may be implemented by hardware components including, for example, at least one digital signal processor (DSP), a processor, a controller, an application-specific integrated circuit (ASIC), a programmable logic element, such as an FPGA, other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The method according to example embodiments may be embodied as a program that is executable by a computer, and may be implemented as various recording media such as a magnetic storage medium, an optical reading medium, and a digital storage medium.

Various techniques described herein may be implemented as digital electronic circuitry, or as computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal for processing by, or to control an operation of a data processing apparatus, e.g., a programmable processor, a computer, or multiple computers. A computer program(s) may be written in any form of a programming language, including compiled or interpreted languages and may be deployed in any form including a stand-alone program or a module, a component, a subroutine, or other units suitable for use in a computing environment. A computer program may be deployed to be executed on one computer or on multiple computers at one site or distributed across multiple sites and interconnected by a communication network.

Processors suitable for execution of a computer program include, by way of example, both general and special purpose microprocessors, and any one or more processors of any kind of digital computer. Generally, a processor will receive instructions and data from a read-only memory or a random access memory or both. Elements of a computer may include at least one processor to execute instructions and one or more memory devices to store instructions and data. Generally, a computer will also include or be coupled to receive data from, transfer data to, or perform both on one or more mass storage devices to store data, e.g., magnetic, magneto-optical disks, or optical disks. Examples of information carriers suitable for embodying computer program instructions and data include semiconductor memory devices, for example, magnetic media such as a hard disk, a floppy disk, and a magnetic tape, optical media such as a compact disk read only memory (CD-ROM), a digital video disk (DVD), etc. and magneto-optical media such as a floptical disk, and a read only memory (ROM), a random access memory (RAM), a flash memory, an erasable programmable ROM (EPROM), and an electrically erasable programmable ROM (EEPROM) and any other known computer readable medium. A processor and a memory may be supplemented by, or integrated into, a special purpose logic circuit.

The processor may run an operating system (OS) and one or more software applications that run on the OS. The processor device also may access, store, manipulate, process, and create data in response to execution of the software. For purpose of simplicity, the description of a processor device is used as singular; however, one skilled in the art will be appreciated that a processor device may include multiple processing elements and/or multiple types of processing elements. For example, a processor device may include multiple processors or a processor and a controller. In addition, different processing configurations are possible, such as parallel processors.

Also, non-transitory computer-readable media may be any available media that may be accessed by a computer, and may include both computer storage media and transmission media.

The present specification includes details of a number of specific implements, but it should be understood that the details do not limit any invention or what is claimable in the specification but rather describe features of the specific example embodiment. Features described in the specification in the context of individual example embodiments may be implemented as a combination in a single example embodiment. In contrast, various features described in the specification in the context of a single example embodiment may be implemented in multiple example embodiments individually or in an appropriate sub-combination. Furthermore, the features may operate in a specific combination and may be initially described as claimed in the combination, but one or more features may be excluded from the claimed combination in some cases, and the claimed combination may be changed into a sub-combination or a modification of a sub-combination.

Similarly, even though operations are described in a specific order on the drawings, it should not be understood as the operations needing to be performed in the specific order or in sequence to obtain desired results or as all the operations needing to be performed. In a specific case, multitasking and parallel processing may be advantageous. In addition, it should not be understood as requiring a separation of various apparatus components in the above described example embodiments in all example embodiments, and it should be understood that the above-described program components and apparatuses may be incorporated into a single software product or may be packaged in multiple software products.

It should be understood that the example embodiments disclosed herein are merely illustrative and are not intended to limit the scope of the invention. It will be apparent to one of ordinary skill in the art that various modifications of the example embodiments may be made without departing from the spirit and scope of the claims and their equivalents.

Accordingly, one of ordinary skill would understand that the scope of the claimed invention is not to be limited by the above explicitly described embodiments but by the claims and equivalents thereof.

What is claimed is:

1. A high-density capacitor comprising:
a metal-oxide-semiconductor (MOS) capacitor, wherein the MOS capacitor includes:
a silicon layer with a dopant concentration of at least 1×10²⁰ cm⁻³;
a first dielectric layer formed above the silicon layer; and
a first metal layer formed above the first dielectric layer.

2. The high-density capacitor of claim 1, further comprising:
a metal-insulator-metal (MIM) capacitor, wherein the MIM capacitor includes
the first metal layer;
a second dielectric layer formed above the first metal layer; and
a second metal layer formed above the second dielectric layer.

3. The high-density capacitor of claim 1, further comprising:
a buried oxide layer formed under the silicon layer; and
a semiconductor substrate formed under the buried oxide layer.

4. The high-density capacitor of claim 2, further comprising:
a buried oxide layer formed under the silicon layer; and
a semiconductor substrate formed under the buried oxide layer.

5. The high-density capacitor of claim 2, wherein the first dielectric layer and the second dielectric layer include the same dielectric material.

6. The high-density capacitor of claim 2, wherein the MOS capacitor and the MIM capacitor have the same area.

7. The high-density capacitor of claim 2, wherein the MOS capacitor and the MIM capacitor are stacked and share at least a portion of the first metal layer.

8. The high-density capacitor of claim 1, wherein the first dielectric layer has a thickness of at least 500 nm.

9. The high-density capacitor of claim 2, wherein the first dielectric layer has a thickness of at least 500 nm.

10. The high-density capacitor of claim 2, wherein the second dielectric layer has a thickness of at least 1000 nm.

11. A method of manufacturing a high-density capacitor including a MOS capacitor, the method comprising:
doping a silicon layer to have a dopant concentration of at least 1×10²⁰ cm⁻³;
forming a first dielectric layer over the silicon layer; and
forming a first metal layer over the first dielectric layer.

12. The method of claim 11, wherein
the high-density capacitor further includes a MIM capacitor, and
the method includes
forming a second dielectric layer over the first metal layer; and
forming a second metal layer over the second dielectric layer.

13. The method of claim 11, further comprising:
forming a semiconductor substrate,
forming a buried oxide layer over the semiconductor substrate, and
forming the silicon layer over the buried oxide layer.

14. The method of claim 12, further comprising:
forming a semiconductor substrate,
forming a buried oxide layer over the semiconductor substrate, and
forming the silicon layer over the buried oxide layer.

15. The method of claim 12, wherein the first dielectric layer and the second dielectric layer include the same dielectric material.

16. The method of claim 12, comprising:
forming the MOS capacitor and the MIM capacitor to have the same area.

17. The method of claim 12, wherein the MOS capacitor and the MIM capacitor are formed such that they are stacked and share at least a portion of the first metal layer.

18. The method of claim 11, comprising:
forming the first dielectric layer to have a thickness of at least 500 nm.

19. The method of claim 12, comprising:
forming the first dielectric layer to have a thickness of at least 500 nm.

20. The method of claim 11, comprising:
forming the second dielectric layer to have a thickness of at least 1000 nm.
